(19) United States
(12) Patent Application Publication
(10) Pub. No.: US 2022/0326357 A1
(43) Pub. Date: Oct. 13, 2022

(54) PHOTONIC INTEGRATED CIRCUIT AND LIGHT DETECTION AND RANGING SYSTEM

(71) Applicant: Intel Corporation, Santa Clara, CA (US)

(72) Inventors: Animesh BANERJEE, San Jose, CA (US); William HAYENGA, Los Angeles, CA (US); Eduardo TEMPRANA GIRALDO, Culver City, CA (US); Pierre DOUSSIERE, Malibu, CA (US); Richard JONES, San Mateo, CA (US); George RAKULJIC, Santa Monica, CA (US)

(21) Appl. No.: 17/848,439

(22) Filed: Jun. 24, 2022

Related U.S. Application Data
(60) Provisional application No. 63/246,800, filed on Sep. 22, 2021.

(51) Int. Cl. G01S 7/4861; G01S 7/484; G01S 17/933; G02B 6/125

(52) U.S. Cl. CPC G01S 7/4861; G01S 7/484; G01S 17/933; G02B 6/125; G02B 2006/12159

(57) ABSTRACT

A photonic integrated circuit including having a semiconductor substrate having integrated a semiconductor light source, the semiconductor light source comprising: an optically active section comprising a gain section and configured to support a first number of wavelengths, an optically passive section comprising a passive waveguide optically coupled to the optically active section and a passive section mirror optically coupled to the passive waveguide, wherein the optically passive section is configured to support a second number of wavelengths that is lower than the first number; and the optically passive section further comprising a signal shifting structure configured to shift a signal of the light supported by the passive waveguide.

### CROSS-REFERENCE

This Application claims priority to U.S. Provisional Application 63/246,800, filed on Sep. 22, 2021, the entire contents of which are incorporated herein by reference.

### TECHNICAL FIELD

This disclosure generally relates to the field of light detection and ranging systems.

### BACKGROUND

A Photonic Integrated Circuit (PIC) is desirable for coherent light detection and ranging (LIDAR) due to the promise of low cost and scalability to high volume. However, due to PIC limitations (size, yield, cost), the number of vertical channels (resolution elements) is limited (˜10's). By using a multiple (M) wavelength laser source and a diffraction grating, for example, the number of LIDAR channels can be increased by a factor of M for a given PIC to achieve a desired high number (>100) of vertical resolution elements or pixels.

Current state-of-the art coherent Frequency Modulated Continuous Wave (FMCW) LIDAR systems require multiple laser sources as source of multiple beams, and discrete optics system to scan the Field of View (FOV) of the LIDAR system using the laser beams. However, using multiple laser sources increases the optical components count and reduces the link budget. Further, in conventional laser source phase noise suppression is required, power consumption for the LIDAR system is relatively high, and back reflection reduces the efficiency of the LIDAR system.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various aspects of the invention are described with reference to the following drawings, in which:

FIG. 1 illustrates a schematic diagram of a vehicle having a LIDAR system;

FIG. 2 illustrates a schematic diagram of a LIDAR system; and FIG. 3A to FIG. 3B illustrate diagrams of an integrated light source for a LIDAR system;

FIG. 4 illustrate a diagram of an integrated light source for a LIDAR system;

FIG. 5 illustrate a diagram of an integrated light source for a LIDAR system;

FIG. 6 illustrate a diagram of an integrated light source for a LIDAR system;

FIG. 7 illustrate a diagram of an integrated light source for a LIDAR system;

FIG. 8A to FIG. 8C illustrate diagrams of an integrated light source for a LIDAR system;

FIG. 9 illustrate a diagram of an integrated light source for a LIDAR system;

FIG. 10 illustrate a diagram of an integrated light source for a LIDAR system;

FIG. 11A to FIG. 11F illustrate diagrams of an integrated light source for a LIDAR system;

FIG. 12A to FIG. 12F illustrate diagrams of an integrated light source for a LIDAR system;

FIG. 13A to FIG. 13C illustrate diagrams of an integrated light source for a LIDAR system; and

FIG. 14 illustrate a diagram of an integrated light source for a LIDAR system;

### DESCRIPTION

The LIDAR system may be used as a component in an autonomous vehicle, autonomous robot, or autonomous UAV or drone, to sense objects, internally as well as externally. The LIDAR system may also be used for assistance systems in vehicles, robots, UAVs or drones. The LIDAR system may be part of a multimodal sensing system, operating alongside or in combination with cameras, radar, ultrasound, or mm-wave ultrawideband (UWB). Navigation and autonomous or assisted decision-making may be based wholly or in part on the LIDAR system. In addition, the LIDAR system may be used in mobile devices such as smartphones, tablets or laptops for purposes including object, person, posture or gesture detection.

The following detailed description refers to the accompanying drawings that show, by way of illustration, specific details and aspects in which the invention may be practiced.

The term “as an example” is used herein to mean “serving as an example, instance, or illustration”. Any aspect or design described herein as “as an example” is not necessarily to be construed as preferred or advantageous over other aspects or designs.

Illustratively, a tunable laser source is provided that allows to selectively provide coherent light of predetermined wavelengths for LIDAR applications. As an example, a low Q multi-wavelength Fabry-Perot laser source coupled to a long external cavity with a passive section tunable filter or mirror and a fast phase modulator is provided. This way, fast wavelength tuning is enabled. The passive section mirror may be a narrow band mirror in case of a broad band passive waveguide, or a broad band mirror in case of a narrow band passive waveguide. As an example, in case of a broad band band mirror, the passive waveguide may support only a single wavelength of the wavelengths provided from the gain section.

Throughout this specification, the term “support” of an optical component, element, or structure may be understood as providing a structure for light of a predetermined wavelength that is to be output, guided, reflected, or to provide a resonant structure for the light of the predetermined wavelength. A predetermined wavelength may be a preset wavelength or desired wavelength.

As an example, a discretely tunable laser source for vertical beam scanning for a light detection and ranging (LIDAR) system in a hybrid (e.g. silicon) photonic integrated circuit (PIC) is provided.

This way, manufacturability of the LIDAR system and/or integration with other photonic components in the PIC is simplified. Alternatively, or in addition, a laser source having a narrow linewidth is provided. This way, phase noise suppression and chirp linearization may be obsolete. Thus, application specific integrated circuit (ASIC) complexity may be reduced. Further this way, power consumption in the LIDAR system may be reduced. Alternatively, or in addition, a laser source is provided that is back reflection tolerant. The laser source may provide optionality for photonic integration with other components. Thus, optical component count and/or the footprint may be reduced.

The laser source may be manufactured in silicon photonics platform, e.g. on the semiconductor substrate. Thus, the laser source may remove the requirement of external vendor lasers and/or drivers. This way, cost may be improved.

The laser source may be discretely tunable and may support multiple wavelengths. This way, only one laser source may be used for the LIDAR system, and, thus, cost of the LIDAR system may be improved. Further, optical link budget may be improved. Further, reliability due to reduction in discrete optical count in the LIDAR system may be improved.

In other words, the source for coherent electromagnetic radiation for a light detection and ranging (LIDAR) system (the source here also denoted as light source or laser source) may be integrated on the semiconductor substrate of a photonic integrated circuit (PIC) of the LIDAR system. The light source may have a low Q factor (LQ) light emitting semiconductor structure (also denoted as optically active section) and a tunable optical cavity (also denoted as optically passive section) having a narrow band filter external to the light emitting semiconductor structure. The external optical cavity, by the narrow band filter, may support only a subset of wavelengths provided from the light emitting semiconductor structure to the external optical cavity.

The light source may be configured for an integrated coherent LIDAR. The light source may be configured to have a tunable (or switchable) output wavelength corresponding to the vertical scanning requirements of the coherent LIDAR system, low phase noise (optical linewidth), e.g. at low frequencies, for long-range detection of targets by the coherent LIDAR system, and high tolerance to optical feedback for integration with other coherent LIDAR components on a PIC. The tunable light source is configured in accordance with the wavelength plan of the coherent LIDAR system and is dynamically set to the desired wavelength per control of the coherent LIDAR system.

A coherent LIDAR system, e.g. implemented on a silicon (Si) PIC, can deliver the high performance and pricing demanded by customers for autonomous vehicle applications. The light source can substantially improve the optical efficiency, performance, cost, and fabrication ease of the product. Thus, an integrated semiconductor laser for coherent LIDAR having a narrow linewidth, being tunable, and being tolerant to optical feedback is provided.

Throughout this specification, a signal shifting structure may be configured to shift the phase, timing, and/or the frequency of a signal. The signal may be light or to be modulated light of the LIDAR system. A signal shifting component may be a phase shifting component or a heating component, as an example.

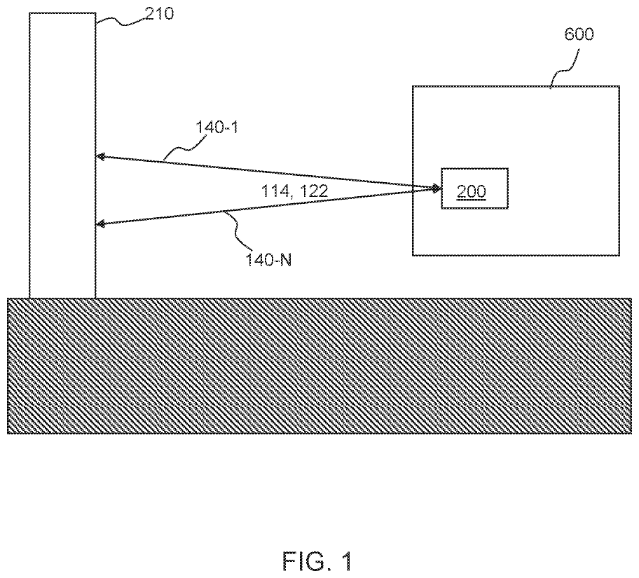

FIG. 1 illustrates a schematic diagram of a vehicle 600 having a LIDAR system 200 integrated therein, as an example. The vehicle 600 may be an unmanned vehicle, e.g. unmanned aerial vehicle or unmanned automobile. The vehicle 600 may be an autonomous vehicle. Here, the LIDAR system 200 may be used to control the direction of travel of the vehicle 600. The LIDAR system 200 may be configured for obstacle detection outside of the vehicle 600, as an example. Alternatively or in addition, the vehicle 600 may require a driver to control the direction of travel of the vehicle 600. The LIDAR system 200 may be a driving assistant. As an example, the LIDAR system 200 may be configured for obstacle detection, e.g. determining a distance and/or direction and relative velocity of an obstacle (target 210) outside of the vehicle 600. The LIDAR system 200 may be configured, along one or more optical channels 140-i (with i being one between 1 to N and N being the number of channels of the PIC), to emit light 114 from one or more outputs of the LIDAR system 200, e.g. outputs of the light paths, and to receive light 122 reflected from the target 210 in one or more light inputs of the LIDAR system 200. The structure and design of the outputs and inputs of the light paths of the LIDAR system 200 may vary depending on the working principle of the LIDAR system 200. Alternatively, the LIDAR system 200 may be or may be part of a spectrometer or microscope. However, the working principle may be the same as in a vehicle 600.

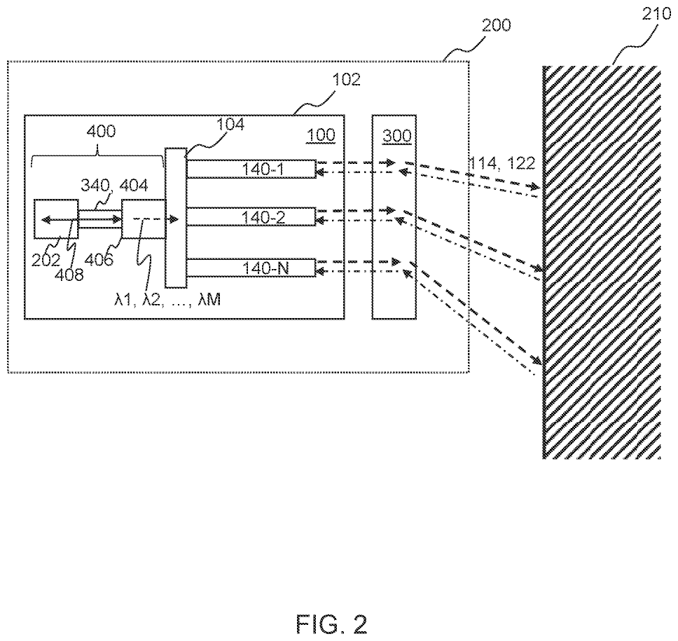

FIG. 2 illustrates a schematic diagram of a LIDAR system 200. The LIDAR system 200 includes photonic integrated circuit (PIC) 100 and an input/output structure 300 (also denoted as I/O structure or optical system) at least optically coupled to the PIC 100.

The photonic integrated circuit 100 may include a semiconductor photonic substrate 102. The semiconductor photonic substrate 102 may have integrated therein at least one light receiving input 104 to branch light received at the at least one light receiving input 104 to a first optical channel 140-1 and a second optical channel 140-2, e.g. of the plurality of optical channels 140-N.

The semiconductor photonic substrate 102 may be made of a semiconductor material, e.g. silicon or gallium nitride. The semiconductor photonic substrate 102 may be a common substrate, e.g. at least for the plurality of optical channels 140-N and the light source 400. The term “integrated therein” may be understood as formed at least in part from the material of the substrate and, thus, may be different to the case in which elements are formed, arranged or positioned on top of a substrate. The PIC includes a plurality of components located next to each other on the same (common) semiconductor substrate. The term “located next” may be interpreted as formed in or on the same (a common) semiconductor photonic substrate 102.

The PIC 100 may include at least one light source 400 integrated on or in the substrate 102 and coupled to the at least one light receiving input 104. The light source 400 may be configured to emit a coherent electromagnetic radiation λ₁, λ₂, . . . , λ_{M}, of one or more wavelength. Throughout this specification any kind of usable of “electromagnetic radiation” is denoted as “light” for illustration purpose only and even though the electromagnetic radiation may not be in the frequency range of visible light, infrared light/radiation or ultraviolet light/radiation. The light source 400 may include a coherent electromagnetic radiation source 202 (also denoted as optically active section including an active gain section) that may also be denoted as coherent light source 400 or light source 400.

The at least one light source 400 may be configured to provide coherent electromagnetic radiation (also denoted as coherent light) to a plurality of optical channels 140-i, e.g. laser radiation in a visible light spectrum, an infrared spectrum, a terahertz spectrum and/or a microwave spectrum. As an example “light” may be visible light, infrared radiation, terahertz radiation or microwave radiation, and the optical components of the LIDAR system 200 may be configured accordingly.

The light source 400 may be configured to be operated as a continuous wave laser and/or a pulsed laser. The light source 400 may be configured to be operated as a continuous wave (CW) laser, e.g. for frequency modulated continuous wave (FMCW) LIDAR in which the frequency of the light input to the input 104 is sweeped or chirped, and/or a pulsed laser, e.g. for time-of-flight (TOF) LIDAR. However, the light source 400 may also be a CW laser, e.g. a CW laser diode, operated in a pulsed mode, e.g. quasi CW (QCW) laser.

The light source 400 may include an optically active section 202 and an optically passive section 340 (see FIG. 3A, and are described in more detail below). The optically passive section 340 may include or may be coupled via an output structure 406 having one or more outputs 418-1, 418-2 to the common input 104 of the optical channels 140-i.

The output structure 406 may include a tap coupler or unidirectional mirror, as an example.

The PIC 100 further includes the plurality of optical channels 140-i each having an input port configured to receive back reflected light 122 from the target 210 and an output port configured to emit light 114 towards the target 210 (in the following also denoted as I/O ports). The I/O ports may be configured according to the PIC and LIDAR layout and design, e.g. according to a monostatic LIDAR having shared I/O ports per light path or a bistatic LIDAR having separated input and output ports per light path.

The one or more outputs I/O of the I/O structure 300 (also denoted as optical system 300) may be configured to emit electromagnetic radiation of the light source 400 to different parts of a target 210, e.g. at the same time or subsequently, e.g. along one or more optical channels 140-i, as illustrated in FIG. 2. This way, light emitted by the output I/O of the PIC 100 samples different portions of the target (not the same pixel) 210 and/or different targets 210 at the same time and allows to adjust the vertical resolution. Thus, light reflected 122 from the target 210 and detected by a photo detector of different light paths contains information correlated to different portions of a target (not the same pixel) and/or different targets at the same time. In other words, a plurality of optical channels 140-N emit light into different directions in space.

As an example, the optical system 300 may include a lens, a grating, a quarter wave plate, and a scanning mirror.

The lens and the grating may be optically arranged to guide light 114 from the output of the PIC 100 to the outside of the LIDAR system 200. The grating structure may be optically arranged to guide light from lens to the outside of the LIDAR system 200.

The grating structure may be a transmission grating, a reflective grating, or a grism.

The lens may be any one of a converging lens, a collimating lens or a diverging lens.

As an example, the lens may be configured and/or may be provided such that light from the outputs I/O of the optical channels 140-i of the plurality of optical channels 140-N have different angles of inclination on a (planar) grating structure. However, the function of the lens and of the grating structure may also be integrated in a single optical element, e.g. a lens-shaped grating. The purpose of the lens and the grating may be to emit parallel light 114 from the outputs I/O of the optical channels 140-i into different directions in space at the same time and receive and detect the light 122 back reflected from a target 210 in the photo detector 122.

A scan mirror may be arranged in the optical channel 140-i between the grating structure and the outside of the LIDAR system 200. The scan mirror may be configured to be movable, e.g. rotatable, to scan the environment of the LIDAR system 200. Alternatively, or in addition, the grating structure may be configured to be movable, e.g. a movable reflection grating.

Further, a quarter wave plate (QWP) or half wave plate (HWP) may be arranged in the light path between the grating structure and the scan mirror.

The LIDAR system 200 may further include a controller. The controller may be configured to control various electronic components, e.g. the light source, optical amplifiers, or other controllable optical components, e.g. a shutter. The controller may be an application specific integrated circuit (ASIC), as an example. The controller be formed from, integrated in or mounted to the semiconductor photonic substrate 102. However, the controller may also be located outside of the PIC 100.

Using a multiple (M) wavelength light source 400 and the grating structure, the number of LIDAR channels may be increased by a factor of M for a given PIC 100 to achieve a desired high number (for example more than 16, e.g. more than 32) of vertical resolution elements or pixels. Hence, a high-performance coherent LIDAR system 200 is achieved. In general, using N parallel optical channels 140-N and M wavelengths in a wavelength-multiplexed LIDAR system 200 results in a total of M*N angular outputs. Hence, the LIDAR system 200 may have a high (>1M pixels/s) overall or effective data rate. The number of PIC channels N to increase the number of vertical resolution elements (or reduce the cost by using fewer or smaller PICs) is readily scalable. The coherent LIDAR with the light source 400 implemented on a silicon PIC will (uniquely) enable the high performance and pricing required by customers for autonomous vehicle applications.

The wavelengths provided from the light source 400 may differ by a few A to a few nm from each other, as an example. The LIDAR system 200 may include one or more light source(s) 400 configured to emit electromagnetic radiation of different/multiple wavelengths/frequencies. The light source 400 may be tunable via a controller to emit light of different predetermined wavelengths.

The optical paths on the PIC may be branched from at least one input 104 to the plurality of outputs I/O. The branching of light 116 from the light source (see also FIG. 2) may be realized by a plurality of optical amplifiers, e.g. SOA, a plurality of optical splitters and a plurality of waveguide structures. The at least one optical splitter may be configured to branch light received at the at least one light receiving input 104 to a plurality of optical channels 140-N. In each optical channel 140-i of the plurality of optical channels 140-N, the photonic integrated circuit 100 may include at least one amplifier structure to amplify the light in the light path to provide an amplified light. Each light path of the plurality of light paths may include at least one light output I/O configured to output the amplified light from the photonic integrated circuit 100 towards the lens of the optical system 300. Each optical channel 140-i of the plurality of optical channels 140-N may include at least one photo detector configured to receive light 122 from the outside of the photonic integrated circuit 100. The at least one photo detector 112 may be located next to the at least one light output I/O, e.g. integrated in the common semiconductor photonic substrate 102.

FIG. 3A and FIG. 3B illustrate schematic diagrams of a tunable laser as light source 400 integrated on the substrate 102 of the PIC 100 of a LIDAR system 200 (see FIG. 2).

The photonic integrated circuit 100 (PIC) may have the semiconductor substrate 102 having integrated the semiconductor light source 400. The semiconductor light source 400 may include the optically active section 202 and the optically passive section 340. The optically active section 202 may include a gain section 304 and may be configured to support a first number of wavelengths (also denoted as first set of wavelengths or frequencies). The optically passive section 340 may include a passive waveguide 404 optically coupled to the optically active section 202 and a passive section mirror 312 optically coupled to the passive waveguide 404. The optically passive section 340 may be configured to support a second number of wavelengths (also denoted as second set of wavelengths or frequencies) that may be lower than the first number (also denoted as subset of the first set).

As an example, the passive section mirror 312 may be a narrow band mirror and the passive waveguide 404 may be a broad band passive waveguide. Alternatively, the passive section mirror 312 may be a broad band mirror and the passive waveguide 404 may be a narrow band passive waveguide. In case of a passive section mirror 312 that is broad band band mirror, the passive waveguide 404 may support only the second number of wavelengths. As an example, the passive waveguide 404 may support only a single wavelength of the first number of wavelengths provided from the gain section 304. Alternatively, as an example, the passive section mirror 312 may be a narrow band mirror or filter, e.g. at least regarding the first mirror 302 and the second mirror 306. The passive section mirror 312 may have a reflectivity of about 100% of incoming light. In other words, the optically passive section may support a lower count (also denoted as number) of wavelengths than the optically active section 202.

As illustrated in FIG. 3A, the optically active section 202 may include a first mirror 302, a second mirror 306, and an optically active gain section 304 arranged between the first mirror 302 and the second mirror 306. The first mirror 302 and the second mirror 306 may be configured as broadband mirrors, e.g. supporting a relatively high number of wavelengths. The first mirror 302 may have a high reflectivity of light provided from the gain section 304, e.g. about 100%. The second mirror 306 may be optically coupled to the optically passive section 340, and may have reflectivity that is lower than the reflectivity of the first mirror 302, e.g. less than 15%, e.g. in a range from 3% to 10%. The first mirror 302 and/or the second mirror 306 may be integrated in the gain section 304, e.g. as a facet of the gain section 304.

Throughout this specification, a waveguide (also denoted as waveguide structure) 404 may be in the form of a strip line or micro strip line. However, a waveguide structure may also be configured as a planar waveguide. The waveguide structure may be configured to guide an electromagnetic radiation emitted from a light source 400 to the output of the optical channels 140-i. The waveguide structure may be formed from the material of the semiconductor photonic substrate 102. Waveguide structures may be optically isolated from each other.

The optically passive section 340 further may include a signal shifting structure (also denoted as signal shifting component) configured to shift a signal of the light supported by the passive waveguide 404. The optically passive section 340 may further include a phase shifting component 308 configured to shift the phase of light supported or guided in the optically passive section 340, as an example a phase tuning heater. The phase shifting component may be part of the signal shifting component, or may be used in addition to the signal shifting component.

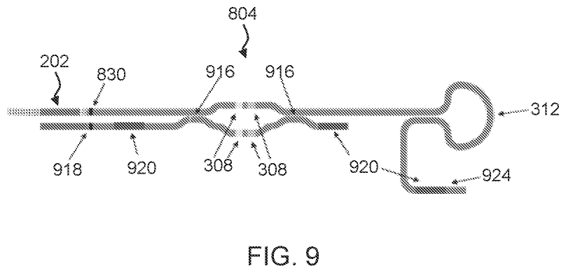

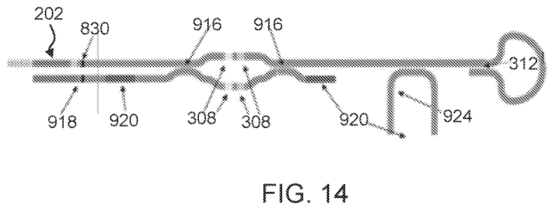

The output structure 406 may include a tap coupler 416 having one or more outputs 418-1, 418-2, as an example (see also FIG. 9 and FIG. 14). Light provided to at least one of the outputs 418-1, 418-2 may be provided via the input 104 to the plurality of optical channels 140-N. The output 418-1, 418-2 may be a multimode interference (MMI) output coupler or directional tap coupler. The output 418-1, 418-2 may be configured to emit a part of the incoming light of less than 5%, e.g. about 2%.

The optically passive section 340 may further include a heating component 310, e.g. as a part of the signal shifting component. The heating component 310 may configured to set, e.g. adjust, a temperature of the third mirror 312. As an example, the signal shifting structure 308 may include the heating component 310 thermally coupled to the passive section mirror 312. The heating component 310 may be configured to set a predetermined temperature of the third mirror 312. A change of temperature of the third mirror 312 may cause a frequency shift of light supported by the optically passive section, as illustrated in FIG. 3B. The frequency shift may be the signal shift. The heating component 310 may be any kind of heating component suitable to heat an optical component.

FIG. 3B illustrates a diagram showing the normalized resonance of power reflection 322 as a function of wavelength 320 for the passive section mirror 312 at a first temperature 324 and a second (higher) temperature 326. Further illustrated is the external grating alignment 328, e.g. the passive section mirror. This way, as an example, the Bragg wavelength of 1320 nm may be temperature tuned to 1320.5 nm to align the resonance of the optically passive section with the resonance of the optically active section.

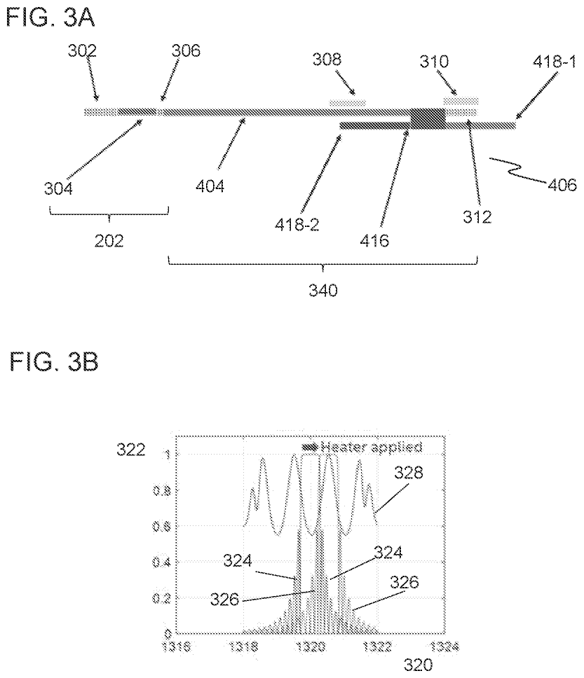

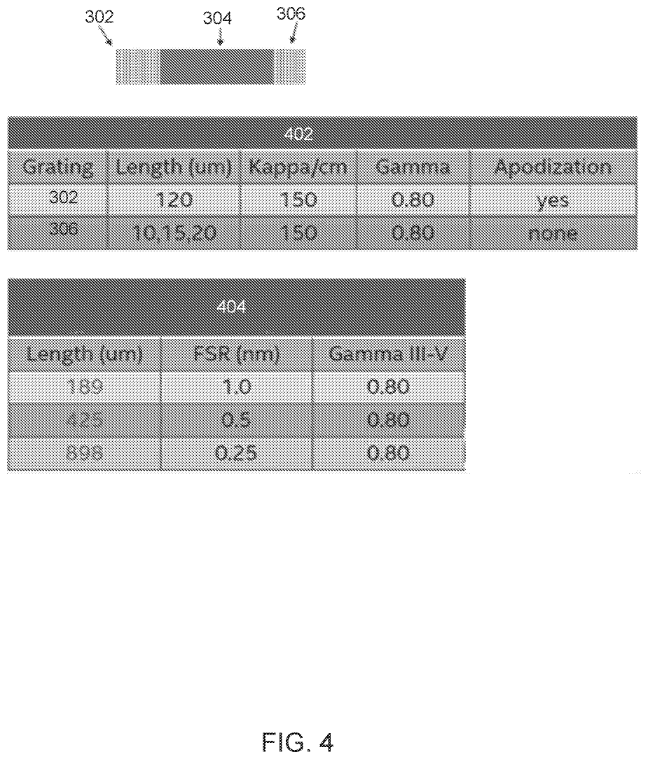

The gain section may be optimized in length, as illustrated in FIG. 4, showing examples for active grating parameters 402 for the first mirror 302 and the second mirror 306, and examples of active section waveguide parameters with the free spectral range (FSR). A typical grating may have a total effective length of about 47.5 μm. A median estimation for the group index may be 3.63. The group index may be used in the active section length calculation.

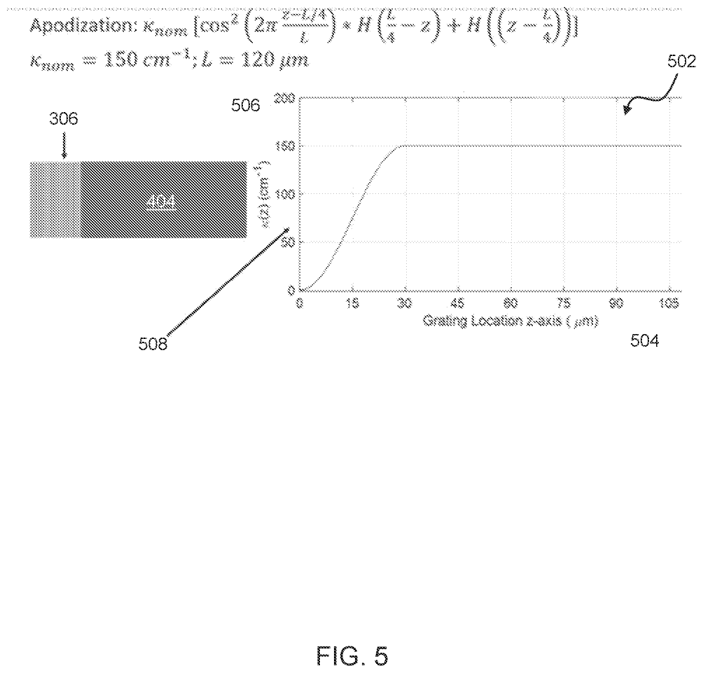

Shown in FIG. 4 are the length in μm (um), the coupling kappa (κ) per cm, gamma and the apodization. The apodization is illustrated in FIG. 5. The calculation basis for the illustrated coupling κₙₒₘ 506 as a function of grating location (z-axis, in μm) 504 is shown in the top of FIG. 5 with values for the first mirror 502. As illustrated 508, the first quarter of the grating is a cos² function, starting at zero and increasing to the maximum, and the last three quarters of the grating is a standard, non-apodized grating.

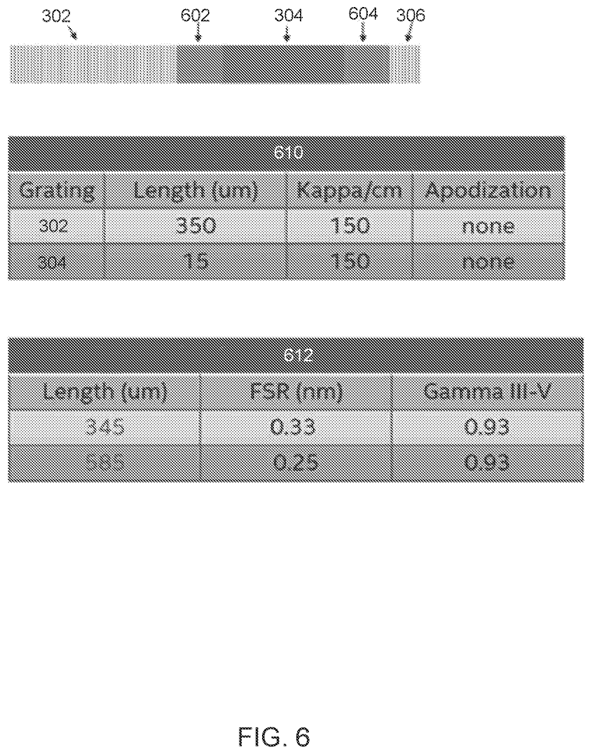

FIG. 6 shows another example wherein the optically active section includes one or more taper section(s) 602, 604 between the mirrors 302, 306 and the active gain section 304. FIG. 6 also shows the calculation of the active section parameters 612 based on the passive grating parameters 610 of the first mirror 302 and the second mirror 306. The group index in each section of the optically active section may be provided before defining the length of the gain section. There may be a large impact to a ring filtering or MZI filtering (see below) if the free spectral range (FSR) is very far off. Hence, the cavity length of the optically active section may be adjusted using the taper section(s) 602, 604.

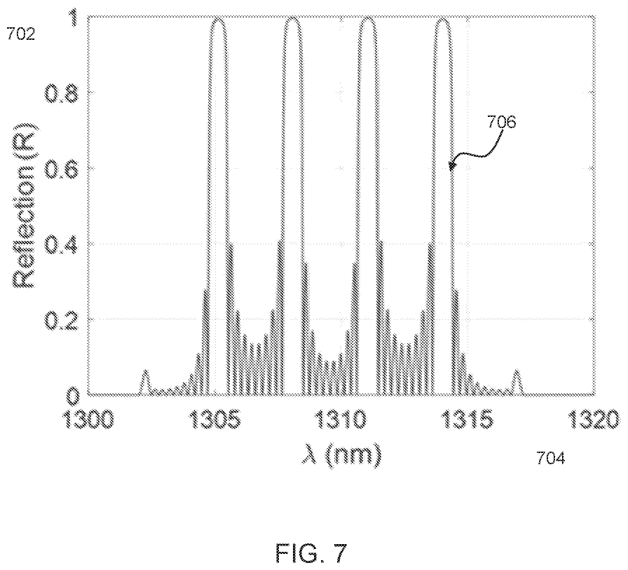

FIG. 7 illustrates an example that the first broadband mirror 302 and/or the second broadband mirror 306 of the optically active section may be configured as sampled DBR grating(s). In FIG. 7, the reflection 702 as a function of wavelength 704 is illustrated for a sampled DBR grating 706. This way, mode selection (e.g. wavelength selection of the light to be emitted by the light source 400) may be improved.

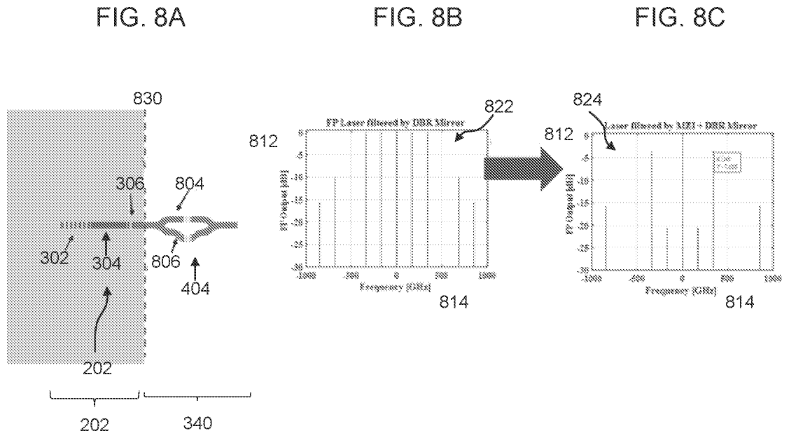

FIG. 8A shows a schematic diagram of another example of a tunable laser as a light source 400. Here, the optically passive section 340 may include a Mach-Zehnder interferometer (MZI) filter 804, e.g. a push-pull MZI filter 804. The MZI filter 804 may cause an optical path length difference ΔL 806. The optical path length difference 806 may be about 0.4 nm when using a broadband mirror as the first mirror 302 having a reflectivity of 100% and thickness of about 4 nm, and a broadband mirror as the second mirror 304 having a reflectivity between 3% to 10%, and a thickness of about 4 nm. The optically active section 302 may thus be configured as a low Q Fabry-Perot (FP) laser. The optically active section 202 may be functionally considered as a pool separated by a pool boundary 830 from the optically passive section 340. FIG. 8B illustrates the output 812 in dB of the FP laser as a function of frequency (in GHz) for a FP laser 822 as optically active section 302 as illustrated in FIG. 8A. The FP laser 302 may create a wavelength (or frequency) comb and the number (also denoted as count) of discrete wavelengths (also denoted as channels) may be set by a DBR (e.g. a sampled DBR instead of a broadband mirror for the first mirror and/or second mirror). The channel may be filtered (also denoted as selected) by the MZI filter 804 of the optically passive section 340 as illustrated in FIG. 8C. The MZI filter 804 may allow for a selection 824 of lasing mode(s). A double pass mode filtering ratio may be larger than 3.6 dB.

Alternatively, or in addition, a heating component (see FIG. 3A) may be thermally coupled to the passive section mirror (not illustrated in FIG. 8A). Alternatively, or in addition, a heating component may be thermally coupled to one or both arms of the MZI filter 804 to tune the optical path length difference 806.

FIG. 9 shows a schematic diagram of another example of a tunable laser as the light source 400. Further to the examples above, the light source 400 may include one or more photo diodes, e.g. for output power detection and wavelength detection, e.g. for controlling the optically active section and/or the frequency selection in the optically passive section. The photo diode may be a III-V monitoring photo diode 918 or a silicon (Si) monitoring photo diode 920, as an example. The photo diode(s) may monitor the light in the optically passive section through or via a waveguide coupled to an output of a tap coupler (e.g. a 3 dB coupler 916) of or integrated in the waveguide 404. Further, in the example illustrated in FIG. 9, the third passive section mirror 312 may be configured as a loop mirror 312 having an output waveguide 924.

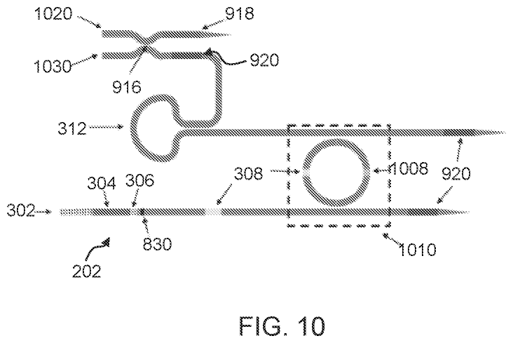

Alternatively, or in addition, as illustrated in FIG. 10, the light source 400 may include a ring filter 1010 in the optically passive section. The ring filter 1010 may include a silicon diode, e.g. a quadrature bias diode (QBD), 1008 and/or a phase tuning heater (QBH) 308.

Further, the optically passive section may include a plurality of outputs, e.g. coupled to photo diodes 918, 920 and or provided to the optical channels of the PIC or other structures, e.g. an output 1030 for an on-chip feedback test structure, an output 1020 to an optical coupler out of the PIC 100.

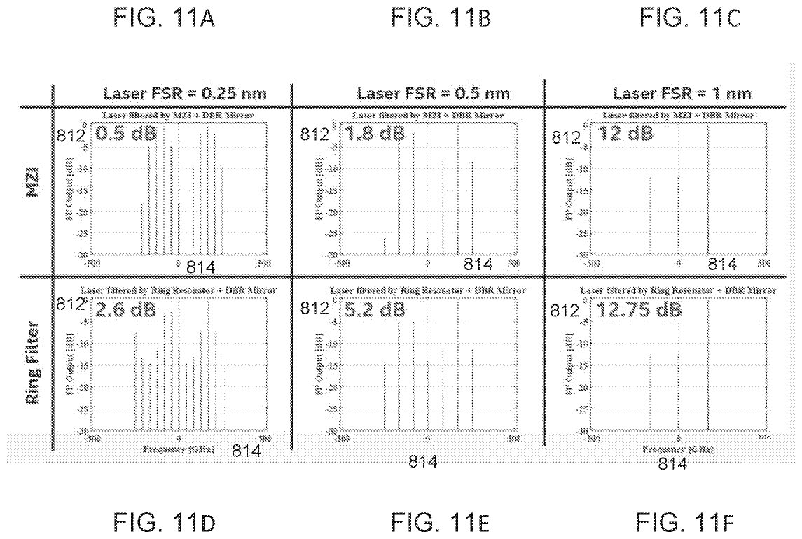

FIG. 11A to FIG. 11F shows a comparison of outputs of an ideal MZI filter (FIG. 11A to FIG. 11C) as illustrated in FIG. 8 and FIG. 9, and a ring filter (FIG. 11D to FIG. 11F) as illustrated in FIG. 10 for different free spectral ranges (FSR)—FIG. 11A and FIG. 11D: FSR=0.25 nm; FIG. 11B and FIG. 11E: FSR=0.5 nm, and FIG. 11C and FIG. 11F: FSR=1 nm. As can be seen, the ring filter provides an improved frequency selection, e.g. as shown by improved side mode suppression ratio (SMSR).

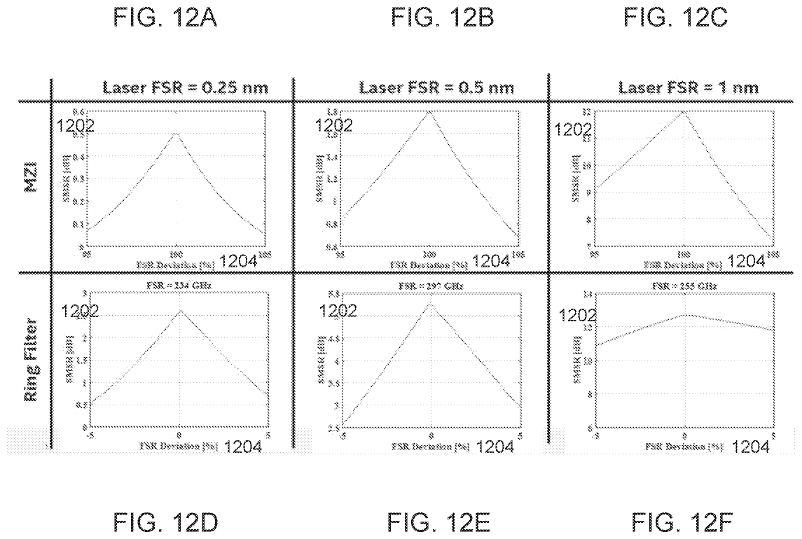

FIG. 12A to FIG. 12F shows a comparison of SMSR (in dB) of the ideal MZI filter (FIG. 12A to FIG. 12C) of the Example of FIG. 11A to FIG. 11C, and the ring filter (FIG. 12D to FIG. 12F) of the Example of FIG. 12D to FIG. 12F. As can be seen, the ring filter provides an improved tolerance. SMSR may degrade less steadily with free-spectral range (FSR) deviation for a ring filter. The FSR variation can be induced by simulation vs fabrication accuracy or run-to-run process variability.

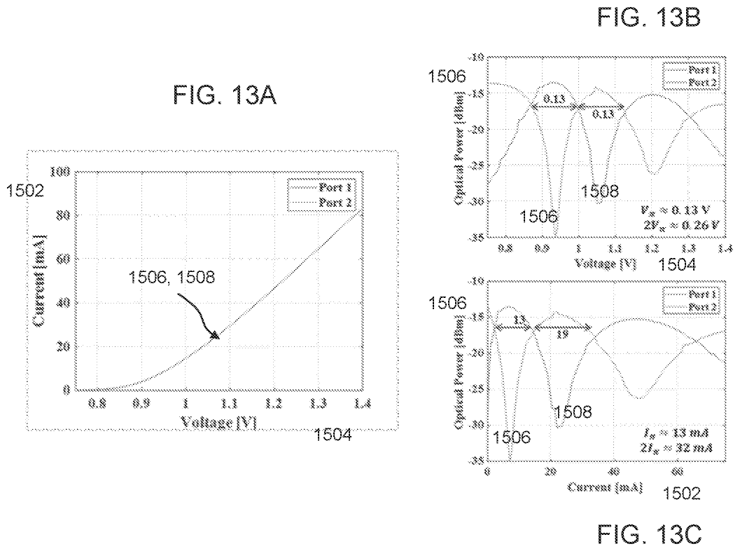

As an example, the QBD may be integrated in the MZI filter 804. The QBD may include a step function 1402. The response 1404 may be the output power of the light source 400 determined via the monitoring photo diode 920 in the time domain. FIG. 13A to FIG. 13C illustrate the QBD response at two different ports 1506, 1508 for current 1502 as a function of voltage 1504 (FIG. 13A), optical output power 1506 as a function of voltage 1504 (FIG. 13B), and optical output power 1506 as a function of current 1502 (FIG. 13C).

FIG. 14 illustrates a schematic diagram of a Tunable Laser 400 using an evanescent coupling of an optical tap for the output waveguide 924 with the waveguide 404 in combination with the loop mirror as third passive section mirror 312. The evanescent coupling is a validated design and the loop mirror has a low loss and a 50%-50% variability of reflectivity and transmittivity. Further, the two outputs of the output waveguide 924 may replace one 1×2 output in a single-sideband (SSB) modulator in the PIC used to modulate the light to be emitted from the LIDAR. Alternatively, the Sagnac configuration illustrated in FIG. 9 may have a partially reflecting loop mirror as third passive section mirror, and the loop mirror may have a low loss. Here, the loop mirror may provide a 46%-54% variability of reflectivity and transmittivity. As an example, the reflectivity may be 42% and reflectivity may be 58%. The Sagnac configuration is a validated design and provides a single output 924. In the Sagnac configuration, an additional 1×2 output may be used for the SSB modulator.

In other words, the signal shifting structure 308 may include a tunable optical filter arranged or integrated along the passive waveguide 404. The tunable optical filter may include a heating component thermally coupled to the optical waveguide 404, and configured to set a predetermined temperature of optical waveguide 404.

The optically active section 202 may include a first broadband mirror 302 and a second broadband mirror 306. The gain section 304 may be optically arranged between the first broadband mirror 302 and the second broadband mirror 306. The first broadband mirror 302 may include a reflectivity of about 100% of light emitted from the gain section 304. The second broadband mirror 306 may be partly transmitting and may include a reflectivity of less than about 15% of light emitted from the gain section 304. The second broadband mirror 306 may include a reflectivity in a range of about 3% to 10% of light emitted from the gain section 304. The first broadband mirror 302 may be configured as a grating. The second broadband mirror 306 may be configured as a grating. The passive section mirror 312 may include a reflectivity of about 100% of light transmitted through the second broadband mirror 306 through the passive waveguide 404 to the passive section mirror 312. The gain section 304 may be configured as a multi-wavelength coherent light emission structure. The passive waveguide 404 may have a linear shape. The PIC 100 further may include a tap coupler 416 integrated on the semiconductor substrate 102, the tap coupler 416 optically coupled to the passive waveguide 404, and may include at least one optical output 418-1, 418-2.

The optically passive section 340 may be configured that the wavelengths of the second number of wavelengths may be a sub-set of the wavelengths of the first number of wavelengths.

The optically passive section 340 may be configured as external optical feedback section for the optically active section 202.

The semiconductor light source 400 may be configured as a distributed Bragg reflector (DBR) laser source.

The optically active section 202 further may include a first taper section 602 optically arranged between the gain section 304 and the first broadband mirror 302. The first taper section 602 may include a passive waveguide 404 forming a predetermined optical distance between the gain section 304 and the first broadband mirror 302.

The optically active section 202 further may include a second taper section 604 optically arranged between the gain section 304 and the second broadband mirror 306. The second taper section 604 may include a passive waveguide 404 forming a predetermined optical distance between the gain section 304 and the second broadband mirror 306.

The semiconductor light source 400 may be configured as a sampled grating distributed Bragg reflector laser source.

The optically passive section 340 further may include a Mach-Zehnder-interferometer (MZI) structure 804.

The MZI structure 804 may include a first optical path having a first optical length and a second optical path have a second optical length shorter than the first length, wherein the second optical path may be at least in part optically parallel to the first optical path. Alternatively, or in addition, the MZI structure 804 may include a first optical path, and a second optical path, and at least one heat component thermally coupled to at least one of the optical path and second optical path.

The MZI structure 804 may include at least one output and at least on photo diode 920 coupled to the output.

The MZI structure 804 further may include a signal shifting structure 308, the signal shifting structure 308 arranged along the passive waveguide 404 and configured to shift a signal of the light supported by the passive waveguide 404.

The passive section mirror 312 may be configured as a loop mirror 312.

The optically passive section 340 further may include a ring filter 1010.

The optically passive section 340 further may include an optical output 418-1, 418-2 coupled to the passive section mirror 312.

The PIC 100 further may include a photo diode 920 coupled to the optical output 418-1, 418-2.

The PIC 100 further may include a controller configured to control the light output of the optically active section 202 and coupled to a photodiode coupled to an output of the optically passive section 340.

The light detection and ranging (LIDAR) system 200 may include the PIC 100 and the optical system 300 configured to guide light from the PIC 100 within an angular range to the outside of the light detection and ranging system.

### EXAMPLES

The examples set forth herein are illustrative and not exhaustive.

Example 1 is a photonic integrated circuit having a semiconductor substrate having integrated a semiconductor light source, the semiconductor light source may include: an optically active section may include a gain section and configured to support a first number of wavelengths, an optically passive section may include a passive waveguide optically coupled to the optically active section and a passive section mirror optically coupled to the passive waveguide, wherein the optically passive section may be configured to support a second number of wavelengths that may be lower than the first number; and the optically passive section further may include a signal shifting structure configured to shift a signal of the light supported by the passive waveguide.

In Example 2, the subject matter of Example 1 can optionally include that the signal shifting structure includes a heating component thermally coupled to the passive section mirror, and configured to set a predetermined temperature of the passive section mirror.

In Example 3, the subject matter of Example 2 can optionally include that the signal shifting structure includes a tunable optical filter arranged or integrated along the passive waveguide.

In Example 4, the subject matter of Example 3 can optionally include that the tunable optical filter includes a heating component thermally coupled to the optical waveguide, and configured to set a predetermined temperature of optical waveguide.

In Example 5, the subject matter of any one of Examples 1 to 4 can optionally include that the optically active section includes a first broadband mirror and a second broadband mirror, wherein the gain section may be optically arranged between the first broadband mirror and the second broadband mirror.

In Example 6, the subject matter of Example 5 can optionally include that the first broadband mirror includes a reflectivity of about 100% of light emitted from the gain section.

In Example 7, the subject matter of Example 5 or 6 can optionally include that the second broadband mirror may be partly transmitting and includes a reflectivity of less than about 15% of light emitted from the gain section.

In Example 8, the subject matter of Exam of any one of Examples 4 to 7 can optionally include that the second broadband mirror includes a reflectivity in a range of about 3% to 10% of light emitted from the gain section.

In Example 9, the subject matter of any one of Examples 1 to 8 can optionally include that the passive section mirror includes a reflectivity of about 100% of light transmitted through the second broadband mirror through the passive waveguide to the passive section mirror.

In Example 10, the subject matter of any one of Examples 1 to 9 can optionally include that the gain section may be configured as a multi-wavelength coherent light emission structure.

In Example 11, the subject matter of any one of Examples 1 to 10 can optionally include that the passive waveguide includes a linear shape.

In Example 12, the subject matter of any one of Examples 1 to 11 can optionally further include a tap coupler integrated on the semiconductor substrate, the tap coupler optically coupled to the passive waveguide, and may include at least one optical output.

In Example 13, the subject matter of any one of Examples 1 to 13 can optionally include that the optically passive section may be configured that the wavelengths of the second number of wavelengths may be a sub-set of the wavelengths of the first number of wavelengths.

In Example 14, the subject matter of any one of Examples 1 to 13 can optionally include that the optically passive section may be configured as external optical feedback section for the optically active section.

In Example 15, the subject matter of any one of Examples 1 to 14 can optionally include that the semiconductor light source may be configured as a distributed Bragg reflector laser source.

In Example 16, the subject matter of any one of Examples 1 to 15 can optionally include that the optically active section further may include a first taper section optically arranged between the gain section and the first broadband mirror, wherein the first taper section includes a passive waveguide forming a predetermined optical distance between the gain section and the first broadband mirror.

In Example 17, the subject matter of any one of Examples 1 to 16 can optionally include that the optically active section further may include a second taper section optically arranged between the gain section and the second broadband mirror, wherein the second taper section includes a passive waveguide forming a predetermined optical distance between the gain section and the second broadband mirror.

In Example 18, the subject matter of any one of Examples 1 to 17 can optionally include that the first broadband mirror may be configured as a grating.

In Example 19, the subject matter of any one of Examples 1 to 18 can optionally include that the second broadband mirror may be configured as a grating.

In Example 20, the subject matter of any one of Examples 1 to 19 can optionally include that the semiconductor light source may be configured as a sampled grating distributed Bragg reflector laser source.

In Example 21, the subject matter of any one of Examples 1 to 20 can optionally include that the optically passive section further may include a Mach-Zehnder-interferometer (MZI) structure.

In Example 22, the subject matter of Examples 21 can optionally include that the MZI structure includes a first optical path having a first optical length and a second optical path have a second optical length shorter than the first length, wherein the second optical path may be at least in part optically parallel to the first optical path.

In Example 23, the subject matter of any one of Examples 21 to 22 can optionally include that the MZI structure includes a first optical path, and a second optical path, and at least one heat component thermally coupled to at least one of the optical path and second optical path.

In Example 24, the subject matter of any one of Examples 21 to 23 can optionally include that the MZI structure includes at least one output and at least on photo diode coupled to the output.

In Example 25, the subject matter of any one of Examples 21 to 24 can optionally include that MZI structure further may include a phase shifting structure, the signal shifting structure arranged along the passive waveguide and configured to shift a signal of the light supported by the passive waveguide.

In Example 26, the subject matter of any one of Examples 1 to 25 can optionally include that the passive section mirror may be configured as a loop mirror.

In Example 27, the subject matter of any one of Examples 1 to 26 can optionally include that the optically passive section further may include a ring filter.

In Example 28, the subject matter of any one of Examples 1 to 27 can optionally include that the optically passive section further may include an optical output coupled to the passive section mirror.

In Example 29, the subject matter of Example 28 can optionally include a photo diode coupled to the optical output.

In Example 30, the subject matter of any one of Examples 1 to 29 can optionally include a controller configured to control the light output of the optically active section and coupled to a photodiode coupled to an output of the optically passive section.

In Example 31, the subject matter of any one of Examples 1 to 30 can optionally include the passive section mirror is a narrow band mirror.

In Example 32, the subject matter of any one of Examples 1 to 31 can optionally include that the passive waveguide supports the second number of wavelengths.

In Example 33, the subject matter of any one of Examples 1 to 32 can optionally include that the passive section mirror supports the second number of wavelengths.

In Example 34, the subject matter of any one of Examples 1 to 32 can optionally include that the passive waveguide supports the second number of wavelengths and passive section mirror supports a number of wavelengths larger than the second number.

In Example 35, the subject matter of any one of Examples 1 to 33 can optionally include that the passive waveguide supports only one of the wavelengths provided by the optically active section.

Example 36 is a light detection and ranging system that may include a photonic integrated circuit according to any one of Examples 1 to 35, and an optical system configured to guide light from the photonic integrated circuit within an angular range to the outside of the light detection and ranging system.

In Example 37, the subject matter of Example 36 can optionally include that wherein the passive waveguide supports the second number of wavelengths and passive section mirror supports a number of wavelengths larger than the second number, and the wavelengths of the second number of wavelengths is a sub-set of the wavelengths of the first number of wavelengths.

Example 38 is a light emitting means having a semiconductor light emitting means integrated on a semiconductor substrate, the semiconductor light emitting means including: an optically active section configured to provide light of a first number of wavelengths, an optically passive section configured to support light of a second number of wavelengths that is lower than the first number, wherein the optically passive section receives light from the optically active section; and wherein the optically passive section further includes a signal shifting means for shifting a signal of the light supported by the optically passive section.

In Example 39, the subject matter of Example 38 can optionally include that the wavelengths of the second number of wavelengths is a sub-set of the wavelengths of the first number of wavelengths. The sound number of wavelengths may be one. In other words, the optically passive section may support only one of the wavelengths of optically active section at a time.

Example 40 is a vehicle that may include a photonic integrated circuit according to any one of Examples 1 to 39.

In Example 41, the subject matter of Example 40 can optionally include that the vehicle may be an unmanned aerial vehicle.

While the invention has been particularly shown and described with reference to specific aspects, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A photonic integrated circuit (PIC) having a semiconductor substrate having integrated a semiconductor light source, the semiconductor light source comprising:
an optically active section comprising a gain section and configured to support a first number of wavelengths,
an optically passive section comprising a passive waveguide optically coupled to the optically active section and a passive section mirror optically coupled to the passive waveguide, wherein the optically passive section is configured to support a second number of wavelengths that is lower than the first number; and
the optically passive section further comprising a signal shifting structure configured to shift a signal of the light supported by the passive waveguide.

2. The PIC of claim 1,
wherein the passive waveguide supports the second number of wavelengths and passive section mirror supports a number of wavelengths larger than the second number.

3. The PIC of claim 1,
wherein the passive waveguide supports only one of the wavelengths provided by the optically active section.

4. The photonic integrated circuit of claim 1,
wherein the signal shifting structure comprises a heating component thermally coupled to the passive section mirror, and configured to set a predetermined temperature of the passive section mirror.

5. The photonic integrated circuit of claim 1,
wherein the signal shifting structure comprises a tunable optical filter arranged or integrated along the passive waveguide.

6. The photonic integrated circuit of claim 1,
wherein the optically active section comprises a first broadband mirror and a second broadband mirror, wherein the gain section is optically arranged between the first broadband mirror and the second broadband mirror.

7. The photonic integrated circuit of claim 6,
wherein the passive section mirror comprises a reflectivity of about 100% of light transmitted through the second broadband mirror through the passive waveguide to the passive section mirror.

8. The photonic integrated circuit of claim 1,
wherein the gain section is configured as a multi-wavelength coherent light emission structure.

9. The photonic integrated circuit of claim 1,
wherein the passive waveguide comprises a linear shape.

10. The photonic integrated circuit of claim 1, further comprising a tap coupler integrated on the semiconductor substrate,
the tap coupler optically coupled to the passive waveguide, and comprising at least one optical output.

11. The photonic integrated circuit of claim 1,
wherein the optically passive section is configured that the wavelengths of the second number of wavelengths is a sub-set of the wavelengths of the first number of wavelengths.

12. The photonic integrated circuit of claim 1,
wherein the semiconductor light source is configured as a distributed Bragg reflector laser source.

13. The photonic integrated circuit of claim 1,
the optically active section further comprising a first taper section optically arranged between the gain section and the first broadband mirror, wherein the first taper section comprises a passive waveguide forming a predetermined optical distance between the gain section and the first broadband mirror.

14. The photonic integrated circuit of claim 1,
the optically active section further comprising a second taper section optically arranged between the gain section and the second broadband mirror, wherein the second taper section comprises a passive waveguide forming a predetermined optical distance between the gain section and the second broadband mirror.

15. The photonic integrated circuit of claim 6,
wherein the second broadband mirror is configured as a grating.

16. The photonic integrated circuit of claim 1,
wherein the semiconductor light source is configured as a sampled grating distributed Bragg reflector laser source.

17. The photonic integrated circuit of claim 1,
the optically passive section further comprising a Mach-Zehnder-interferometer (MZI) structure.

18. The photonic integrated circuit of claim 1,
wherein the passive section mirror is configured as a loop mirror.

19. The photonic integrated circuit of claim 1,
the optically passive section further comprising a ring filter.

20. The photonic integrated circuit of claim 1,
the optically passive section further comprising an optical output coupled to the passive section mirror.

21. A light detection and ranging (LIDAR) system, comprising
a photonic integrated circuit having a semiconductor substrate having integrated a semiconductor light source, the semiconductor light source comprising:
an optically active section comprising a gain section and configured to support a first number of wavelengths,
an optically passive section comprising a passive waveguide optically coupled to the optically active section and a passive section mirror optically coupled to the passive waveguide, wherein the optically passive section is configured to support a second number of wavelengths that is lower than the first number; and
the optically passive section further comprising a signal shifting structure configured to shift a signal of the light supported by the passive waveguide, and the light detection and ranging system further comprising:
an optical system configured to guide light from the photonic integrated circuit within an angular range to the outside of the light detection and ranging system.

22. The LIDAR system of claim 21,
wherein the passive waveguide supports the second number of wavelengths and passive section mirror supports a number of wavelengths larger than the second number, and
wherein the wavelengths of the second number of wavelengths is a sub-set of the wavelengths of the first number of wavelengths.

23. A light emitting means having a semiconductor light emitting means integrated on a semiconductor substrate, the semiconductor light emitting means comprising:
an optically active section configured to provide light of a first number of wavelengths,
an optically passive section configured to support light of a second number of wavelengths that is lower than the first number, wherein the optically passive section receives light from the optically active section; and
wherein the optically passive section further comprises a signal shifting means for shifting a signal of the light supported by the optically passive section.

24. The light emitting means of claim 23,
wherein the wavelengths of the second number of wavelengths is a sub-set of the wavelengths of the first number of wavelengths.
